(19) United States
(12) Patent Application Publication
(10) Pub. No.: US 2026/0271636 A1
(43) Pub. Date: Sep. 10, 2026

(54) METHOD OF FORMING A DIELECTRIC LAYER

(71) Applicant: ASM IP Holding B.V., Almere (NL)

(72) Inventor: Kamesh Mullapudi, Tempe, AZ (US)

(21) Appl. No.: 19/555,993

(22) Filed: Mar. 4, 2026

Related U.S. Application Data
(60) Provisional application No. 63/768,254, filed on Mar. 7, 2025.

(51) Int. Cl. H10P 14/60; H10P 14/69

(52) U.S. Cl. CPC H10P 14/6544; H10P 14/6339; H10P 14/6548; H10P 14/6909; H10P 14/6912; H10P 14/6914

(57) ABSTRACT

Methods for forming a dielectric layer in a feature, where the dielectric layer may be free of voids and/or seams, are disclosed. An exemplary method includes providing a substrate comprising one or more features in a reaction chamber, depositing a dielectric layer in the one or more features, and performing a treatment. The treatment may change the crystal structure from a first crystal structure to a second crystal structure. The treatment may remove voids and/or seams from the dielectric layer.

### CROSS-REFERENCE TO RELATED APPLICATIONS

This application is a nonprovisional of, and claims priority to and the benefit of, U.S. Provisional Patent Application No. 63/768,254, filed Mar. 7, 2025 and entitled “METHOD OF FORMING A DIELECTRIC LAYER,” which is hereby incorporated by reference herein.

### FIELD

The disclosure generally relates to methods of and apparatuses for forming electronic devices. More particularly, examples of the disclosure relate to a method for forming a dielectric layer, to a structure comprising a dielectric layer, and a substrate processing apparatus for forming a dielectric layer.

### BACKGROUND

Dielectric layers are used in a wide variety of electronic devices, such as semiconductor devices. Typical dielectric layer deposition techniques work relatively well in a variety of applications. However, the formation of dielectric layers in features, such as gaps or trenches has proven challenging. Conventional methods of forming dielectric layers in some high aspect ratio features result in dielectric material with voids or seams, particularly as the size of the feature decreases and/or an aspect ratio of the feature increases. The presence of voids or seams in a dielectric layer often degrades the dielectric layers structural integrity or electrical properties. Accordingly, there exists a desire for improved methods of and apparatuses for depositing dielectric layers in features that mitigate formation of voids and/or seams with the dielectric material.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to methods for forming a dielectric layer in one or more features and/or removing one or more voids and/or seams from a dielectric layer. As set forth below, methods described herein may be used in the fabrication of electronic devices, such as semiconductor devices.

According to one or more embodiments, a method of forming a dielectric layer is provided. An exemplary method includes providing a substrate in a reaction chamber, the substrate comprising one or more features, depositing a dielectric layer in the one or more features, and performing a treatment on the dielectric layer. The dielectric layer may include one or more seams and/or voids. The dielectric layer may be or include a metal oxide, such as an oxide of one or more of hafnium, zirconium, aluminum, titanium, scandium, yttrium, lanthanum, tantalum, and niobium. Performing the treatment can change a crystal structure of the dielectric layer from a first crystal structure to a second crystal structure, where the first crystal structure is different than the second crystal structure. Performing the treatment may increase a volume of the dielectric layer (e.g., the volume of the dielectric layer may increase by between about 3% and about 7%). Performing the treatment may remove the one or more voids and/or seams.

Performing the treatment may induce a stress on the dielectric layer, thereby inducing the change in the crystal structure of the dielectric layer. In some embodiments, performing the treatment may include one or more of heating the substrate to a temperature greater than 300° C., providing an inert gas at a temperature between 350° C. and about 450° C. and a pressure between about 0.1 torr and about 60 torr, exposing the substrate to a reactive plasma, laser annealing the dielectric layer, and/or forming a stress layer directly on the dielectric layer, where the stress layer has a different lattice constant that the dielectric layer. In some embodiments that include forming a stress layer, the stress layer may be removed after the dielectric layer changes the crystal structure.

In accordance with further examples of the disclosure, a device is formed using a method and/or includes a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a dielectric layer and/or removing one or more voids and/or seams from a dielectric layer in accordance with one or more embodiments of the disclosure;

FIG. 2 illustrates a method for depositing a dielectric layer in one or more features in accordance with one or more embodiments of the disclosure;

FIG. 3 illustrates a method for performing a treatment on a dielectric layer in accordance with one or more embodiments of the disclosure;

FIG. 4 illustrates an example of a substrate processing apparatus in accordance with one or more examples of the disclosure;

FIG. 5 illustrates an example of a structure that can form part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to necessarily limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium.

The terms “precursor” and “reactant” can refer to molecules or compounds that participate in a chemical reaction that produces a layer or deposited material. A precursor typically contains portions that are at least partly incorporated into a layer. Such resulting portions may be deposited on a substrate to form a film as disclosed herein. A reactant may be a compound that is incorporated into the layer or that is not incorporated into the resulting layer to a significant extent. In some cases, the term reactant can be used interchangeably with the term precursor.

As used herein, a “metal precursor” includes a gas or a material that can become gaseous and that can be represented by a chemical formula that includes one or more metals.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

As used herein, the term “structure” can refer to a partially or completely fabricated device structure. By way of examples, a structure can be a substrate or include a substrate with one or more layers and/or features formed thereon.

As used herein, the term “overlying” can refer to a film (e.g., directly) on top of another film.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

A carrier and/or inert gas can be (e.g., continuously) co-flowed throughout any steps or sub-steps of any methods described herein. By way of example, a carrier and/or an inert gas can be one or more of helium, argon, or nitrogen.

Various steps of methods described herein can be performed within a single reaction chamber or can be performed in multiple reaction chambers, such as reaction chambers of a cluster tool. In some embodiments, the methods may take place in a single reaction space. In some embodiments, one or more steps or substeps of methods described herein may take place in different reaction spaces and/or a different reaction chambers.

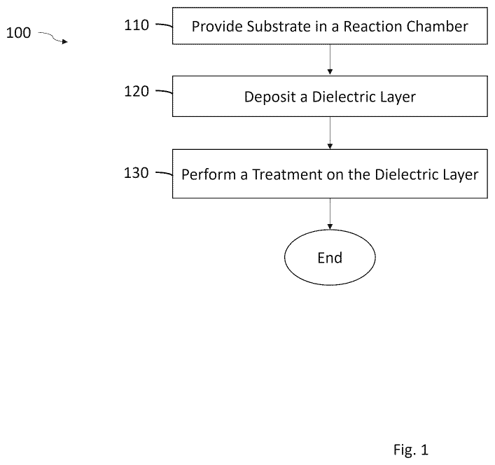

FIG. 1 illustrates a method 100 for forming a dielectric layer and/or removing one or more voids and/or seams from the dielectric layer in accordance with exemplary embodiments of the disclosure. Method 100 includes providing a substrate within a reaction chamber (step 110), depositing a dielectric layer in one or more features (step 120), and performing a treatment on the dielectric layer (step 130).

The substrate provided during step 110 includes one or more features on a surface of the substrate. The features may be gaps, trenches, or the like. The one or more features may have an aspect ratio greater than 1, or greater than 5, or greater than 10, or greater than 25. The exemplary features may have a depth greater than 50 Angstroms, or between about 50 and 200 Angstroms. Additionally or alternatively, the one or more features may have a width greater than 10 Angstroms, or greater than 20 Angstroms, or between about 40 and 60 Angstroms.

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. A pressure within a reaction space can be less than 760 torr, or between about 1 torr and 500 torr, or between about 1 torr and about 100 torr.

The method 100 continues with depositing a dielectric layer in the one or more features (step 120). Depositing the dielectric layer 120 may be done with any suitable method. In some embodiments, depositing the dielectric layer comprises a chemical vapor deposition process and/or a cyclical vapor deposition process (e.g., an atomic layer deposition process or a cyclical chemical vapor deposition process). In some embodiments, the depositing the dielectric layer comprises a conformal deposition process. In some embodiments, depositing the dielectric layer forms one or more voids or seams in the dielectric layer.

In some embodiments, the dielectric layer comprises an electrical insulator. In some embodiments, the dielectric layer comprises a high-k dielectric (e.g., the dielectric layer has a dielectric constant greater than 4, or greater than 10, or greater than 20). In some embodiments, the dielectric layer comprises a metal oxide. In some embodiments, the dielectric layer comprises one or more of hafnium, zirconium, aluminum, titanium, scandium, yttrium, lanthanum, tantalum, and niobium. By way of examples, the dielectric layer comprises one or more of HfO₂, ZrO₂, and HfZrO₄.

In some embodiments, the dielectric layer comprises a dopant. In some embodiments, the dopant comprises one or more of yttrium, magnesium, cerium, or aluminum. In some embodiments, the dielectric layer comprises about 0.1 at % to about 5 at % dopant, or about 0.5 at % to about 3 at % dopant, or about 1 at % to about 2 at % dopant. Not to be bound by theory, the presence of the dopant in the dielectric layer may stabilize the first crystal structure of the dielectric layer.

In accordance with further examples, the dielectric layer, as provided or as deposited, has a first crystal structure. In some embodiments, the first crystal structure is monocrystalline. In some embodiments, the first crystal structure comprises a plurality of monocrystalline portions. In some embodiments, the first crystal structure comprises a seam separating different monocrystalline portions. In some embodiments, the first crystal structure comprises a monoclinic or triclinic crystalline structure. In some embodiments, the first crystal structure comprises a monoclinic crystalline structure. In some embodiments, a portion greater than 50%, or greater than 75%, or greater than 90% of the first crystal structure is a monoclininc or triclinic crystalline structure.

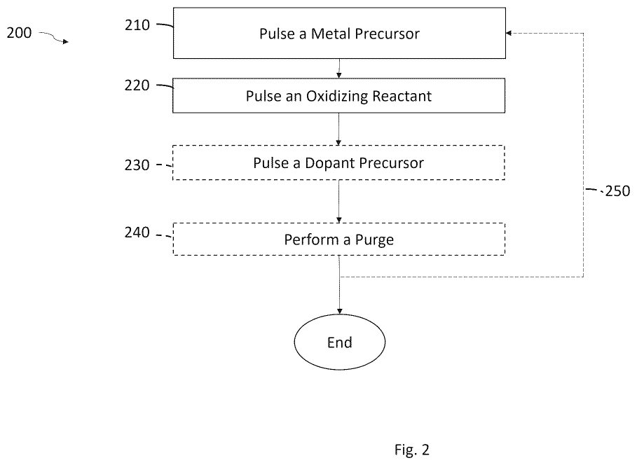

FIG. 2 illustrates a method 200 suitable for step 120 in FIG. 1. Method 200 comprises pulsing a metal precursor (step 210), pulsing an oxidizing reactant (step 220), optionally pulsing a dopant (step 230), optionally performing a purge (step 240), and optionally repeating the steps one or more times (loop 250). In some cases, the steps 210-240 of method 200 may be performed in any order. Each step 210-240 of method 200 may be performed once or a plurality of times before proceeding to the next step. In some embodiments, a purge, such as purge 240, is performed after any or all of the steps 210-230 of pulsing a metal precursor 210, pulsing an oxidizing reactant 220, and pulsing a dopant precursor 230.

In some embodiments, the metal precursor comprises one or more of hafnium, zirconium, aluminum, titanium, scandium, yttrium, lanthanum, tantalum, and niobium. In some embodiments, the oxidizing reactant comprises oxygen. By way of examples, the oxidizing reactant may be oxygen (O₂), ozone (O₃), H₂O, hydrogen peroxide, an alcohol, and/or oxygen radicals.

In some embodiments, the dopant precursor comprises yttrium, magnesium, cerium, or aluminum. The dopant precursor may contain at least one metal different than a metal in the metal precursor.

Turning back to FIG. 1, performing the treatment 130 changes a crystal structure of the dielectric layer from a first crystal structure to a second crystal structure, wherein the first crystal structure is different than the second crystal structure. Performing the treatment may induce a stress on the dielectric layer, thereby inducing the change in the crystal structure of the dielectric layer. In some embodiments, performing a treatment changes the crystal structure of the dielectric layer from the first crystal structure to a second crystal structure, wherein the first crystal structure is different than the second crystal structure. In some embodiments, the second crystal structure is monocrystalline. In some embodiments, the second crystal structure comprises fewer monocrystalline portions than the first crystal structure. In some embodiments where the first crystal structure comprises a seam separating different monocrystalline portions, the second crystal structure does not comprise the seam separating different monocrystalline portions or comprises fewer of such seams. In some embodiments, the second crystal structure comprises a cubic, tetragonal, orthorhombic, or hexagonal crystalline structure. In some embodiments, the second crystal structure comprises a tetragonal crystalline structure. In some embodiments, a portion greater than 50%, or greater than 75%, or greater than 90% of the second crystal structure is a cubic, tetragonal, orthorhombic, or hexagonal crystal structure.

Performing the treatment 130 may increase a volume of the dielectric (e.g., increase the volume of the dielectric layer by between about 2% and about 8%, or about 3% and about 7%, or about 4% and about 6%).

In some embodiments, performing the treatment comprises removing one or more seams or voids from the dielectric layer. In some embodiments, the dielectric layer comprises less seams or voids after performing the treatment. In some embodiments, the dielectric layer comprises (e.g., substantially or essentially) no seams or voids after performing the treatment.

In some embodiments, performing the treatment may include one or more of heating the substrate to a temperature between about 350° C. and 450° C., or between about 375° C. and about 425° C.; providing an inert gas at a temperature above 300° C., or between 300° C. and 500° C., or between 350° C. and 450° C., and a pressure between 0.1 torr and 100 torr, or between 1 torr and 60 torr, or between about 5 torr and 20 torr; exposing the substrate to a reactive plasma; laser annealing the dielectric layer; and/or forming a stress layer overlying the dielectric layer, where the stress layer has a different lattice constant that the dielectric layer.

In some embodiments where performing a treatment includes of heating the substrate and/or providing an inert gas, a duration of heating the substrate and/or providing an inert gas is less than 20 minutes, or less than 3 minutes, or less than 1 minute, or between about 10 seconds and about 30 seconds.

Exposing the substrate to a reactive plasma comprises generating a hydrogen plasma, an oxygen plasma and/or an ammonia plasma, and exposing the substrate to the plasma or to species generate by the plasma. A hydrogen plasma may be formed from a hydrogen-containing gas, such as H₂, H₂O, hydrazine or the like. An oxygen plasma may be formed from a oxygen-containing gas, such as O₂, O₃, N₂O, H₂O, or the like. An ammonia plasma may be formed from a gas comprising ammonia. In some embodiments, exposing the substrate to a reactive plasma comprises etching a portion of the layer. Not to be bound by theory, it is believed that etching a portion of the layer causes stress on the layer and can change the crystal structure of the layer.

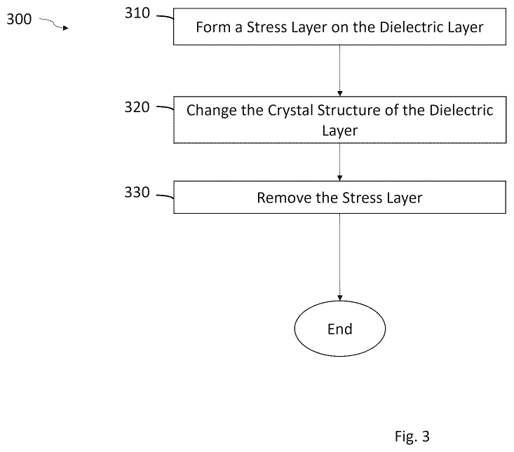

FIG. 3 illustrates a method 300 suitable for step 130 in FIG. 1. Method 300 comprises forming a stress layer (e.g. directly) on the dielectric layer (step 310), changing the crystal structure of the dielectric layer (step 320), followed by removing the stress layer (step 330). The stress layer may be formed by any suitable method, including a chemical vapor deposition process, a cyclical vapor deposition process, an epitaxial process, or a sputtering process. The stress layer has a different lattice constant than the dielectric layer. In some embodiments, the stress layer has a larger (e.g., greater than 10%, or greater than 25%) lattice constant than the dielectric layer. In some embodiments, the stress layer has a smaller (e.g., smaller than 10%, or smaller than 25%) lattice constant than the dielectric layer. In some embodiments, the stress layer comprises boron nitride, aluminum nitride, silicon carbide, indium nitride, titanium nitride, germanium, or magnesium oxide. The difference in lattice constant puts a stress on the dielectric layer and may cause a change in the crystal structure of the dielectric layer.

The stress layer may be removed (step 330) by any suitable method, including an etch process or a polish process. In some embodiments, removing the stress layer comprises exposing the substrate to an etch gas. In some embodiments, the etch gas may comprise fluorine (F₂), chlorine (Cl₂), ammonia (NH₃), oxygen radicals, or radicals produced in an ammonia plasma.

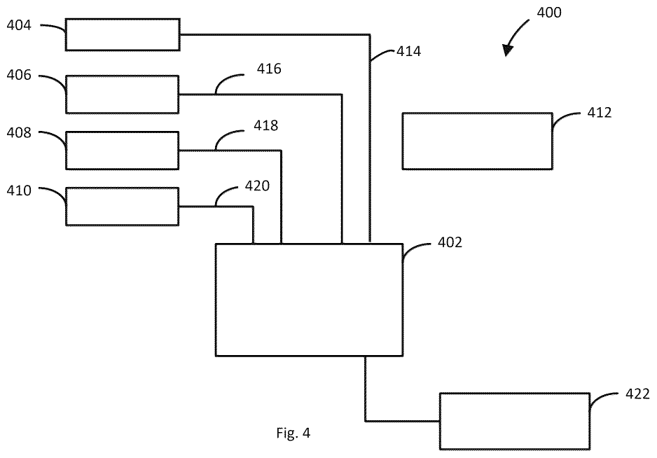

FIG. 4 illustrates an example of a substrate processing apparatus 400 in accordance with one or more examples of the disclosure. Apparatus 400 can be used to perform a method as described herein and/or form a structure or device portion as described herein.

In the illustrated example, apparatus 400 includes one or more reaction chambers 402, a metal precursor source 404, an oxidizing reactant gas source 406, an etch gas source 408, an inert gas source 410, an exhaust source 422, and a controller 412.

Reaction chamber 402 can include any suitable reaction chamber, such as an atomic layer deposition (ALD) or chemical vapor deposition (CVD) reaction chamber.

Metal precursor gas source 304 can include a vessel and one or more metal precursors as described herein—alone or mixed with one or more carrier (e.g., inert) gases. Oxidizing reactant gas source 406 can include a vessel and one or more oxidizing reactants as described herein—alone or mixed with one or more carrier (e.g., inert) gases. Etch gas source 408 can include a vessel and one or more of etch gases as described herein—alone or mixed with one and/or more carrier gases. Inert gas source 410 can include a vessel and one and/or more inert gases, such as nitrogen, helium, or argon. Although illustrated with four gas sources 404-410, apparatus 400 can include any suitable number of gas sources. Gas sources 404-410 can be coupled to reaction chamber 402 via lines 414-420, which can each include flow controllers, valves, heaters, and the like.

Exhaust source 422 can include one or more vacuum pumps.

Controller 412 includes electronic circuitry and software to selectively operate valves, manifolds, heaters, pumps, and other components included in the apparatus 400. Such circuitry and components operate to introduce precursors, reactants, and gases from the respective sources 404-410. Controller 412 can control timing of gas pulse sequences, temperature of the substrate and/or reaction chamber, pressure within the reaction chamber, and various other operations to provide proper operation of the apparatus 400. Controller 412 can include control software to electrically or pneumatically control valves to control flow of precursors, reactants, and purge gases into and out of the reaction chamber 402. Controller 412 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 400 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 402. Further, as a schematic representation of a system, many components have been omitted for simplicity of illustration, and such components may include, for example, various valves, manifolds, purifiers, heaters, containers, vents, and/or bypasses.

During operation of apparatus 400, substrates, such as semiconductor wafers (not illustrated), are transferred from, e.g., a substrate handling system to reaction chamber 402. Once substrate(s) are transferred to reaction chamber 402, one or more gases from gas sources 404-410, such as precursors, reactants, carrier gases, and/or purge gases, are introduced into reaction chamber 402.

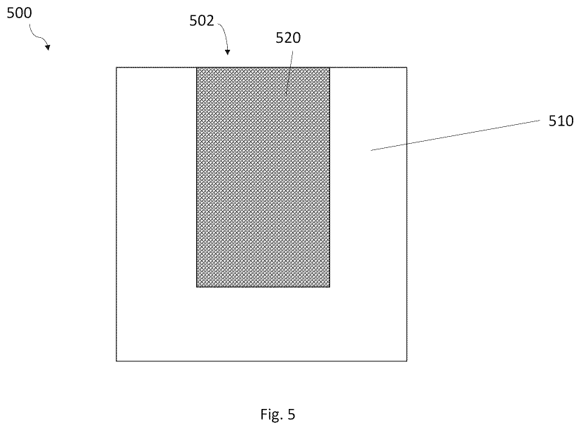

FIG. 5 illustrates a structure/a portion of a device 500 in accordance with additional examples of the disclosure. Device or structure 500 includes a substrate 510, comprising one or more features 502, and a dielectric layer 520. The one or more features may have an aspect ratio greater than 5, or greater than 10, or greater than 25, and other dimensions, such as those described above. By way of examples, the substrate comprises silicon or silicon germanium. In some embodiments, dielectric layer 520 comprises a metal oxide, such as an oxide of one or more of hafnium, zirconium, aluminum, titanium, scandium, yttrium, lanthanum, tantalum, and niobium. In some embodiments, dielectric layer 520 comprises a dopant. In some embodiments, the dopant may be one or more of yttrium, magnesium, cerium, or aluminum. In some embodiments, dielectric layer 520 comprises between about 0.5 at % and about 5 at % dopant, or between about 1 at % and about 2 at % dopant. The dielectric layer has a crystal structure. In some embodiments, the crystal structure is monocrystalline. In some embodiments, the crystal structure comprises a cubic, tetragonal, orthorhombic, or hexagonal crystalline structure. In some embodiments, a portion greater than 50%, or greater than 75%, or greater than 90% of the crystal structure is a cubic, tetragonal, orthorhombic, or hexagonal crystalline structure. In some embodiments, dielectric layer 520 is (e.g., substantially or essentially) free of voids and/or seams.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a dielectric layer, the method comprising:
providing a substrate comprising one or more features on a surface of the substrate;
depositing a dielectric layer in the one or more features;
performing a treatment to change a crystal structure of the dielectric layer from a first crystal structure to a second crystal structure, wherein the first crystal structure is different than the second crystal structure.

2. The method of claim 1, wherein depositing the dielectric layer comprises depositing a dielectric layer with one or more seams or voids, and wherein performing the treatment comprises removing the one or more seams or voids from the dielectric layer.

3. The method of claim 1, wherein the second crystal structure is a tetragonal crystal structure.

4. The method of claim 1, wherein the first crystal structure is a monoclinic crystal structure.

5. The method of claim 1, wherein an aspect ratio of the one or more features is greater than 25.

6. The method of claim 1, wherein performing the treatment increases a volume of the dielectric layer.

7. The method of claim 1, wherein performing the treatment on the dielectric layer increases a volume of the dielectric layer by between about 3% and 7%.

8. The method of claim 1, wherein depositing the dielectric layer comprises a cyclical deposition process.

9. The method of claim 1, wherein depositing the dielectric layer comprises a conformal deposition process.

10. The method of claim 1, wherein the dielectric layer comprises a metal oxide.

11. The method of claim 1, wherein the dielectric layer comprises one or more of a hafnium, zirconium, aluminum, titanium, scandium, yttrium, lanthanum, tantalum, and niobium.

12. The method of claim 1, wherein the dielectric layer comprises one or more HfO₂, ZrO₂, and HfZrO₄.

13. The method of claim 1, wherein the dielectric layer comprises between 0.1 at % and 5 at % dopant, wherein the dopant comprises yttrium, magnesium, cerium, or aluminum.

14. A method for forming a dielectric layer, the method comprising:
providing a substrate comprising one or more features on a surface of the substrate;
depositing a dielectric layer in the one or more features, wherein the dielectric layer comprises one or more seams or voids; and
treating the dielectric layer, wherein treating the dielectrics layer removes the one or more seams or voids,
wherein treating the dielectric layer comprises heating the substrate to a temperature between about 350° C. and about 450° C., or providing an inert gas at a temperature above 300° C. and a pressure between about 0.1 Torr and 60 Torr, exposing the substrate to a reactive plasma, laser annealing the dielectric layer, or forming a stress layer directly on the dielectric layer, wherein the stress layer has a different lattice constant that the dielectric layer.

15. The method of claim 14, wherein treating the dielectric layer comprises heating the substrate to a temperature between about 350° C. and about 450° C.

16. The method of claim 14, treating the dielectric layer comprises forming the stress layer directly on the dielectric layer, wherein the stress layer comprises one or more of boron nitride, aluminum nitride, silicon carbide, indium nitride, titanium nitride, germanium, and magnesium oxide.

17. The method of claim 14, wherein treating the dielectric layer comprises forming the stress layer directly on the dielectric layer.

18. The method of claim 17, further comprising removing the stress layer.

19. The method of claim 14, wherein treating the dielectric layer changes a crystal structure of the dielectric layer from a first crystal structure to a second crystal structure.

20. A method for removing one or more voids or seams from a dielectric layer, the method comprising:
providing a substrate comprising the dielectric layer in one or more features on a surface of the substrate wherein the dielectric layer comprises one or more seams or voids; and
treating the dielectric layer, wherein treating the dielectric layer changes a crystal structure of the dielectric layer form a first crystal structure to a second crystal structure and removes the one or more seams or voids,
wherein treating the dielectric layer comprises heating the substrate to a temperature between about 350° C. and about 450° C., or providing an inert gas at a above 300° C. and a pressure between about 0.1 Torr and 60 Torr, exposing the substrate to a reactive plasma, laser annealing the dielectric layer, or forming a stress layer directly on the dielectric layer, wherein the stress layer has a different lattice constant that the dielectric layer.
